(19) United States
(12) Patent Application Publication
(10) Pub. No.: US 2025/0233563 A1
(43) Pub. Date: Jul. 17, 2025

(54) COMMON-GATE AMPLIFYING ARRANGEMENT

(71) Applicant: Infineon Technologies AG, Neubiberg (DE)

(72) Inventor: Peter UNTERKIRCHER, Engerwitzdorf (AT)

(21) Appl. No.: 18/990,292

(22) Filed: Dec. 20, 2024

(30) Foreign Application Priority Data
Jan. 12, 2024 (DE) 102024200254.2

(51) Int. Cl. H03F 3/45

(52) U.S. Cl. CPC H03F 3/45179; H03F 2200/36; H03F 2203/45024

(57) ABSTRACT

A common-gate amplifying arrangement. The common-gate amplifying arrangement includes a common-gate amplifier and an inner regulated cascode. The inner regulated cascode amplifies a signal provided by the common-gate amplifier, which is responsive to an input signal.

### CROSS-REFERENCE TO RELATED APPLICATION

This application claims priority to Germany Patent Application No. 102024200254.2 filed on Jan. 12, 2024, the content of which is incorporated by reference herein in its entirety.

### TECHNICAL FIELD

The present disclosure relates to the field of amplifiers, and in particular to amplifiers for use with radar receivers.

### BACKGROUND

The amplification of signals is an important function in many electronic and electrical applications, including radar circuitry. The desired characteristics of an amplifying arrangement will depend upon the use-case scenario in which the amplifying arrangement is employed. For instance, an amplifying arrangement for use in a radar receiver would be advantageous if it were able to provide low noise and high spurious free dynamic range (SFDR) amplification, in order to reduce a likelihood of generating fake or false targets.

It has been identified that the amplification of signals in a radar receiver is a dominant contributor to the SFDR characteristics of a radar receiver. Thus, it has been herein identified that a bottleneck for improvements to SFDR inside a radar receiver is that of the amplifying arrangement used. The amplification of signals needs to be both fast (high gain-band-width (GBW)) and have sufficient DC-gain to operate over a wide output range, e.g., achieve amplification with a high SFDR.

There is therefore a desire to provide an amplifying arrangement with improved characteristics for use in radar circuitry, especially for use in radar receivers.

### SUMMARY

Examples disclosed herein propose a common-gate amplifier arrangement. The common-gate amplifier arrangement includes a common-gate amplifier and an inner regulated cascode.

The common-gate amplifier is configured to receive a voltage at an input node and to produce a first voltage based on the received voltage at an intermediate node. The inner regulated cascode is connected to the intermediate node. The inner regulated cascode is configured to amplify the first voltage to produce an amplified voltage at an output node.

Proposed approaches make use of a common-gate amplifier, adding a regulated (inner) cascode on top in order to boost dc-gain and at the same time provide high gain bandwidth (GBW) of the structure. This gives a current source with high output impedance which provides excellent intermodulation product features. Thus, the common-gate amplifier finds particular use when employed within a radar receiver for performing high fidelity amplification of an input signal with a high GBW and with a good DC gain.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a common-gate amplifier arrangement.

FIG. 2 illustrates a comparative example of a common-gate amplifier arrangement;

FIG. 3 illustrates an amplifying arrangement.

FIG. 4 illustrates another amplifying arrangement.

FIG. 5 illustrates another common-gate amplifier arrangement.

FIG. 6 illustrates a single-ended amplifying arrangement.

FIG. 7 illustrates a differential amplifying arrangement.

FIG. 8 illustrates a radar receiving arrangement.

### DETAILED DESCRIPTION

The examples described herein provide a common-gate amplifying arrangement. The common-gate amplifying arrangement includes a common-gate amplifier and an inner regulated cascode. The inner regulated cascode amplifies a signal provided by the common-gate amplifier, which is responsive to an input signal.

For the sake of this description, conventional labelling terms may be used for the various elements and voltage related to any transistor. More particularly, the term GX is used to refer to the X-th gate (where X is any integer), the term SX is used to refer to the X-th source (where X is any integer, and the term DX is used to refer to the X-th drain (where X is any integer). Similarly, the term V_{GX} is used to refer to the voltage at the X-th gate (where X is any integer), the term V_{SX} is used to refer to the voltage at the X-th source (where X is any integer) and the term V_{DX} is used to refer to the voltage at the X-th drain (where X is any integer).

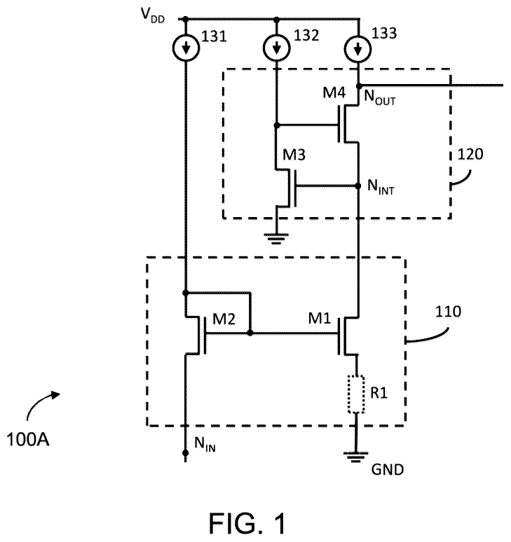

FIG. 1 illustrates a common-gate amplifier arrangement 100A.

The common-gate amplifier arrangement 100A is configured for performing high gain amplification of a signal or voltage, whilst maintaining a high gain bandwidth (GBW). The proposed approach also provides an amplifier arrangement with a high output impedance.

The common-gate amplifier arrangement 100A comprises a common-gate amplifier 110 and an inner regulated cascode 120. The common-gate amplifier 110 receives a voltage (e.g., an input voltage) at an input node N_{IN} and produces a first voltage (at an intermediate node N_{INT}) based on the received voltage. The inner regulated cascode 120 is connected to the intermediate node N_{INT} and is configured to amplify the first voltage to produce an amplified voltage at an output node N_{OUT}.

In the illustrated example, the common gate amplifier 110 takes the form of a regulated common-gate amplifier. More specifically, the common gate amplifier 110 comprises a first transistor M1 and a diode-connected transistor M2. It is possible to define a respective source, gate and drain for each transistor. Thus, the first transistor M1 comprises a first source, a first gate, and a first drain. Similarly, the diode-connected transistor comprises a second source, a second gate, and a second drain. The first drain is directly connected to the intermediate node N_{INT}. The first source is connected to a ground or reference voltage GND. The first gate is connected to the second gate. The nature of the diode-connected transistor M2 means that the second drain is (directly) connected to the second gate.

In the illustrated example, the common-gate amplifier 110 further comprises a first resistive arrangement R1 connecting the first source to the ground or reference voltage GND. The first resistive arrangement R1 has a first resistance and may comprise one or more resistors. The first resistive arrangement may, in some examples, be omitted. In particular, the first resistive arrangement may be omitted if the first transistor M1 and the diode-connected transistor M2 are appropriately unbalanced, e.g., the aspect ratio (e.g., width/length) of the first transistor M1 is less than the aspect ratio of the second transistor M2. For instance, the length of the first transistor M1 and the second transistor M2 may be the same, but the width of the second transistor M2 may be greater than (e.g., no less than 5× greater than, e.g., no less than 10× greater than) the width of the first transistor M1.

In the illustrated example, the inner regulated cascode comprises a first cascode transistor M3 and a second cascode transistor M4. The first and second cascode transistors are arranged in a regulated cascode structure with respect to the first transistor M1. Conceptually, the first transistor M1 and the second cascode transistor M4 are connected to form a cascode. The first cascode transistor M3 acts to regulate the second cascode transistor M4.

The first cascode transistor M3 has a third source, a third gate, and a third drain. The third gate is connected to the intermediate node N_{INT}. The third source is connected to a ground or reference voltage GND, optionally via a further resistive arrangement (not illustrated in FIG. 1).

The second cascode transistor M4 has a fourth source, a fourth gate, and a fourth drain. The fourth drain is connected to the output node N_{OUT}. The fourth gate is connected to the third drain. The fourth source is connected to the intermediate node N_{INT}.

The common-gate amplifier arrangement 100A may comprise a respective current source 131, 132, 133 for providing a respective current to the second drain, the third drain and the fourth drain. Thus, the common-gate amplifier may further comprise a first current source 131 configured to provide a current to the second drain. Similarly, the inner regulated cascode may comprise a second current source 132 configured to provide a current to the third drain and a third current source 133 configured to provide a current to the fourth drain.

In some examples, the current provided by the first current source and the current provided by the third current source are substantially the same (e.g., substantially the same magnitude or substantially equal). In some examples, the current provided by the second current source is substantially the same as the current provided by the first current source and/or the current provided by the third current source. Such approaches help ensure that the first transistor M1 (current source 131) and the second transistor M2 see substantially the same current, such that the gate-source voltage of these transistors is approximately the same.

The skilled person would readily appreciate and select an appropriate current for use with the desired use-case scenario and/or component values of the common-gate amplifier arrangement. For instance, a suitable value for a current provided by any of the first, second and third current sources may be a value between 50 μA and 1 mA, e.g., between 50 μA and 500 μA, e.g., between 100 μA and 500 μA. A working example of a suitable value of the current provided by any of the first, second and third current sources (if present) is 300 μA.

The proposed common-gate amplifier increases a dc-gain of amplification, whilst at the same time providing a high GBW of the structure. This gives a current source with high output impedance which provides excellent intermodulation product features.

The gain A₀ of the common-gate amplifier arrangement 100A, is defined by the following equation:

$${A}_{0} = \frac{{V}_{out}}{{V}_{in}} = {g}_{m 1} {r}_{o 1} ( \frac{{r}_{o 4}}{{r}_{o 1}} + {g}_{m 4} . {r}_{o 4} . {g}_{m 3} {r}_{o 3} + {g}_{m 4} {r}_{o 4} + 1 ) \qquad ( 1 )$$

As defined in the standard hybrid-pi model terminology, the term gₘ₁ represents the transconductance of the first transistor M1, rₒ₁ represents the output resistance of the first transistor M1, rₒ₄ represents the output resistance of the second cascode transistor M4, gₘ₄ represents the transconductance of the second cascode transistor M4, gₘ₃ represents the transconductance of the first cascode transistor M3, and rₒ₃ represents the output resistance of the first cascode transistor M3. V_{OUT} is the voltage at the output node N_{OUT}. V_{IN} is the voltage at the input node N_{IN}.

The gain A₀ can be approximated by the following equation, due to dominating factors in the gain defined by equation (1):

$${A}_{0} \approx {g}_{m 1} . {r}_{o 1} . {g}_{m 4} {r}_{o 4} . {g}_{m 3} {r}_{o 3} \qquad ( 2 )$$

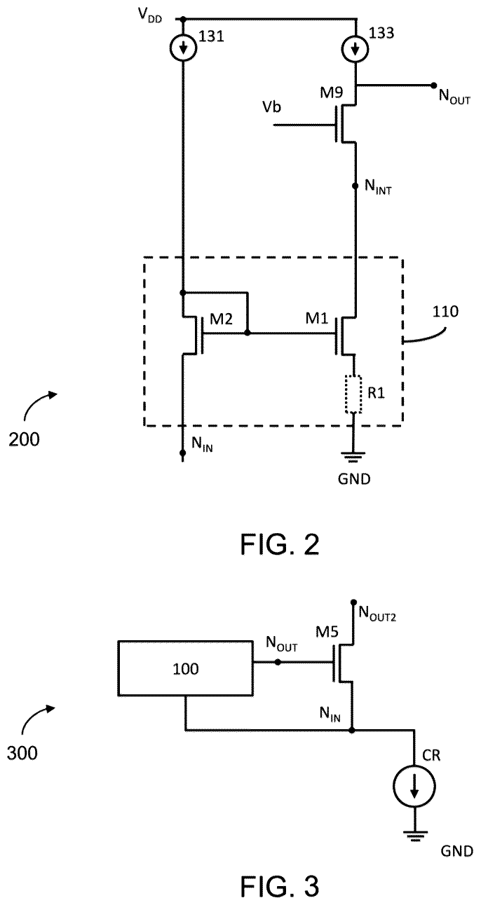

FIG. 2 provides a comparative example of a common-gate amplifier arrangement 200 in which the inner regulated cascode (of the previously proposed common-gate amplifier arrangement) is replaced by a single transistor M9. The single transistor M9 forms a non-regulated cascode with the first transistor M1.

The gain A_{O2} of the comparative example of the common-gate amplifier arrangement 200 is defined by the following equation:

$${A}_{02} = \frac{{V}_{out}}{{V}_{in}} = {g}_{m 1} ( {r}_{o 1} + {r}_{o 9} + {g}_{m 9} . {r}_{o 9} . {r}_{o 1} ) \qquad ( 3 )$$

As defined in the standard hybrid-pi model terminology, the term gₘ₁ represents the transconductance of the first transistor M1, rₒ₁ represents the output resistance of the first transistor M1, rₒ₉ represents the output resistance of the single transistor M9, gₘ₉ represents the transconductance of the single transistor M9. V_{OUT} is the voltage at the output node N_{OUT}. V_{IN} is the voltage at the input node N_{IN}.

The gain A_{O2} can be approximated by the following equation, due to dominating factors in the gain defined by equation (3):

$${A}_{02} \approx {g}_{m 1} . {r}_{o 1} . {g}_{m 9} . {r}_{o 9} \qquad ( 4 )$$

Thus, by a direct comparison of equations (2) and (4), it can be seen that (assuming the transconductance and output resistance of all transistors is nearly the same), the gain of the proposed common-gate amplifier arrangement 100 is gₘ₃·rₒ₃ times greater than the gain of the comparative examples of the common-gate amplifier arrangement 200. Thus, there is a significant improvement in gain if using an inner regulated cascode 120, e.g., compared to a basic cascode arrangement.

FIG. 3 illustrates an amplifying arrangement 300 according to a proposed approach. The amplifying arrangement 300 comprises a herein disclosed common-gate amplifier arrangement 100 (comprising a common-gate amplifier and inner regulated cascode). The amplifying arrangement further comprises a current regulator CR and a pass transistor M5.

The current regulator CR is connected between the input node N_{IN} of the common-gate amplifier arrangement and a ground voltage or a reference voltage GND. The current regulator CR may comprise a current source arrangement and/or a second resistive arrangement. A suitable example of a current source arrangement will be described later in this disclosure.

The advantage of using a current source arrangement compared to a (second) resistive arrangement is its higher output impedance. This helps reduce current for a same SFDR performance or increase SFDR performance for the same current.

The pass transistor M5 comprises a fifth source, a fifth gate, and a fifth drain. The fifth source is connected to the input node N_{IN} of the common gate amplifier arrangement. The fifth gate is connected to the output node N_{OUT} of the inner regulated cascode. The fifth drain is connected to a second output node N_{OUT2}. The second output node N_{OUT2} provides an amplified version of the signal provided at the input node N_{IN}.

The amplifying arrangement acts to regulate the input current to the common-gate amplifier arrangement, as well as to increase an output resistance of the overall amplifying of an input signal (e.g., defined at the input node N_{IN}).

In an alternative version of an amplifying arrangement, the current regulator CR of the amplifying arrangement 300 is replaced by a push-pull output interface. In particular, the current regulator may be replaced by a push-pull pass device, with an additional quiescent current regulation arrangement also being provided. This can configure the amplifying arrangement to operate or function as, for instance, an output interface of a Class A amplifier. In this approach, the pass transistor M5 may operate as a further cascode transistor for a push-pull pass device that replaces the current regulator CR.

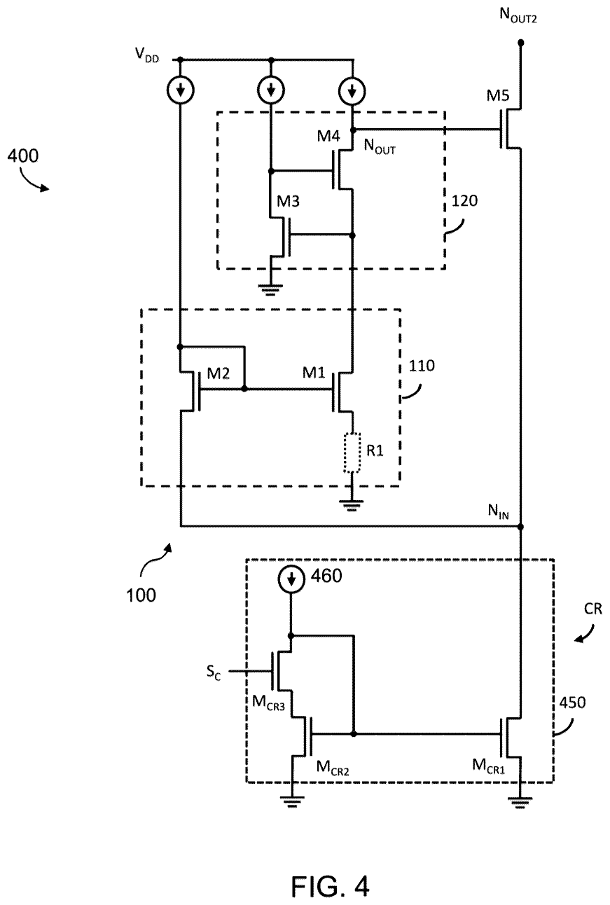

FIG. 4 provides a circuit diagram example of the amplifying arrangement 300, in which the current regulator CR comprises a current source arrangement 450.

The current source arrangement 450 functions as a current mirror. In particular, a first M_{CR1} and second M_{CR2} current source transistor are arranged in a basic metal-oxide semiconductor field-effect transistor (MOSFET) current mirror configuration. In particular, a drain current of the second current source transistor M_{CR2} is mirrored in the drain current of the first current source transistor M_{CR1}. The drain of the first current source transistor is connected to the input node N_{IN}, to thereby define the signal at the input node N_{IN}. A third current source transistor M_{CR3} is connected between the drain of the second current source transistor and a current source 460. Controlling the current supplied by the current source controls the drain current of the second current source transistor M_{CR2} (when the third current source transistor M_{CR3} is activated), and therefore the drain current at the first current source transistor M_{CR1}. The magnitude of the current provided by the current source 460 (and the ratio between the aspects ratios of the first and second current source transistors) define the current supplied to the input node from the current source arrangement 450.

The function and operation of the current source arrangement 450 illustrated in FIG. 4 would be readily apparent to the skilled person.

The skilled person would similarly be capable of replacing the current source arrangement 450 of FIG. 4 with any other form of current source arrangement, e.g., comprising a current mirror, a constant-current source circuit, an (active) constant current circuit. A wide variety of examples are known in the art, such as those disclosed in Harrison, Linden T. Current Sources and Voltage References: A Design Reference for Electronics Engineers. Elsevier, 2005. The skilled person would be readily capable of selecting and/or adapting any suitable current source circuit for use in the present disclosure.

The high ohmic node at the gate of the pass device M5 acts as the dominant pole.

With continued reference to FIG. 4, the output resistance R_{OUT} of the amplifying arrangement 400 is defined by the following equation:

$${R}_{OUT} = {r}_{oCR 1} + {r}_{o 5} + ( {A}_{O} + 1 ) {g}_{m 5} . {r}_{o 5} . {r}_{oCR 1} \qquad ( 5 )$$

As defined in the standard hybrid-pi model terminology, the term r_{oCR1} represents the output resistance of the first current source transistor M_{CR1}, rₒ₅ represents the output resistance of the pass transistor M5, A₀ represents the gain of the common-gate amplifier arrangement 100A (previously defined in equation 1 and approximated in equation (2)), and gₘ₅ represents the transconductance of the pass transistor M5.

The output resistance R_{OUT} (at the second output node N_{OUT2}) can be approximated by the following equations, due to dominating factors in the output resistance defined by equation (5) and the gain A_{O} defined by equation (1) and approximated by equation (2):

$${R}_{OUT} \approx ( {A}_{O} + 1 ) {g}_{m 5} . {r}_{o 5} . {r}_{oCR 1} \qquad ( 6 )$$

$${R}_{OUT} \approx {( {g}_{m} {r}_{o} )}^{4} . {r}_{o} \qquad ( 7 )$$

Equation (7) holds under the assumption that the transconductance and output resistance of all transistors in the common-gate amplifier arrangement are substantially the same, and can be approximated by gₘ and rₒ respectively.

If the common-gate amplifier arrangement 100 (illustrated in FIGS. 1 and 4) was replaced with the comparative example of a common-gate amplifier arrangement 200 in which the inner regulated cascode (of the previously proposed common-gate amplifier arrangement) is replaced by a single transistor M9 (illustrated in FIG. 2), then the output resistance R_{OUT2} of the amplifying arrangement would be defined by the following equation:

$${R}_{OUT 2} = {r}_{oCR 1} + {r}_{o 5} + ( {A}_{O 2} + 1 ) {g}_{m 5} . {r}_{o 5} . {r}_{oCR 1} \qquad ( 8 )$$

The output resistance R_{OUT2} can be approximated by the following equations, due to dominating factors in the output resistance defined by equation (8) and the gain A_{O2} defined by equation (3) and approximated by equation (4):

$${R}_{OUT 2} \approx ( {A}_{O 2} + 1 ) {g}_{m 5} . {r}_{o 5} . {r}_{oCR 1} \qquad ( 9 )$$

$${R}_{OUT 2} \approx {( {g}_{m} {r}_{o} )}^{3} . {r}_{o} \qquad ( 10 )$$

Like equation (7), equation (10) holds under the assumption that the transconductance and output resistance of all transistors in the common-gate amplifier arrangement are substantially the same, and can be approximated by gₘ and rₒ respectively.

Thus, it can be clearly seen that the approximate output resistance of the amplifying arrangement is increased by a factor of gₘ·rₒ if the herein proposed common-gate amplifier arrangement 100 is used, rather than the comparative example of a common-gate amplifier arrangement.

In the previously illustrated and described examples, the transistors used in the common-gate amplifier arrangement comprise (only) NFETs, e.g., NMOSFETs. As such, the previously disclosed common-gate amplifier arrangements may be labelled NFET common-gate amplifier arrangements. The previously disclosed amplifying arrangement may be labelled an NFET amplifying arrangement.

However, the skilled person would be readily capable of modifying the illustrated circuits for use for PFETs, e.g., PMOSFETs. The term “NFET” refers to an n-channel FET, such as an n-channel MOSFET. The term “PFET” refers to a p-channel FET, such as a p-channel MOSFET.

Suitable examples of FETs that may be employed for use as any herein disclosed transistor are well known to the skilled person, any may include MOSFETs, JFETs, GaN FETs, OFETs and so on.

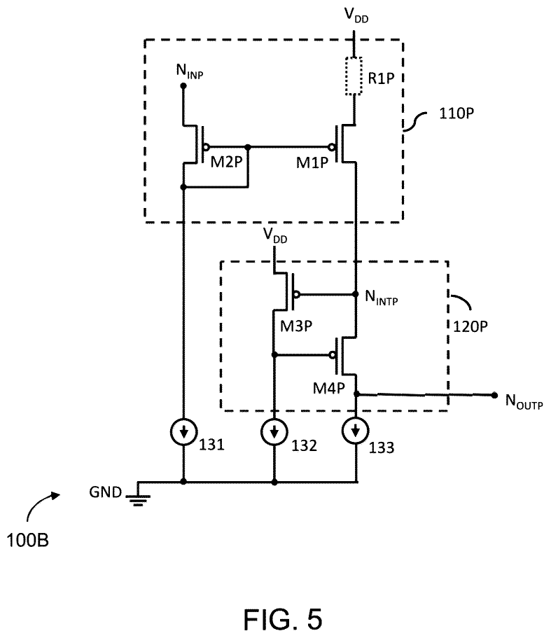

FIG. 5 illustrates an example of a proposed common-gate amplifier arrangement 100B comprises PFETs in place of the NFETs previously used. Other elements of the common-gate amplifier arrangement 100B are modified accordingly. The skilled person would be readily capable of modifying or adjusting elements of the common-gate amplifier arrangement 100B to achieve desired goals or meet certain use-case scenarios.

A common-gate amplifier arrangement that uses (only) PFETs (as exemplified by the arrangement 100B illustrated by FIG. 5) may be labelled a PFET common-gate amplifier arrangement. An amplifying arrangement that makes use of (only) a PFET common-gate amplifier arrangement may be labelled a PFET amplifying arrangement.

For the sake of illustrative clarity, in FIG. 5, reference numerals for elements in the PFET common-gate amplifier arrangement have been appended with the suffix “P” to distinguish from those of the NFET common-gate amplifier arrangement. Their function and purpose will be readily apparent to the appropriately skilled person.

The herein proposed common-gate amplifier arrangements (and amplifying arrangements) can be used for a variety of purposes. In particular, proposed common-gate amplifier arrangements may be integrated or used as amplifiers or interfaces in a variety of different circuit arrangements, particularly those used for radar circuitry and more particularly radar receiving arrangements. Some examples of possible use-case scenarios for proposed common-gate amplifiers are hereafter described.

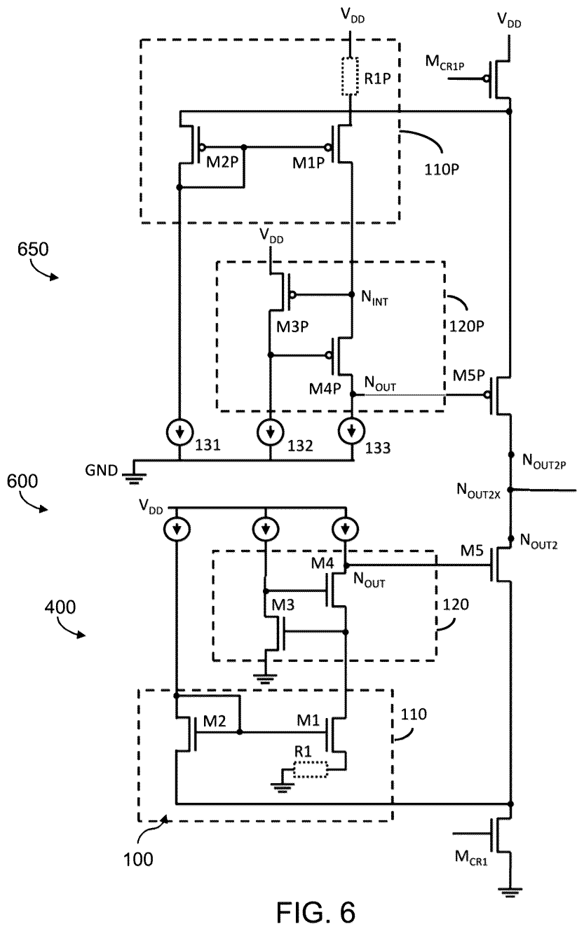

FIG. 6 illustrates a single-ended amplifying arrangement 600. The single-ended amplifying arrangement comprises an NFET amplifying arrangement 400 and a PFET amplifying arrangement 650.

For the sake of illustrative clarity, in FIG. 6, reference numerals for elements in the PFET amplifying arrangement have been appended with the suffix “P” to distinguish from those of the NFET common-gate amplifying arrangement. Their function and purpose will be readily apparent to the appropriately skilled person.

The NFET amplifying arrangement 400 operates as a first amplifying arrangement, in which each transistor is an NFET. The PFET amplifying arrangement 650 operates as a second amplifying arrangement, in which each transistor is an PFET.

For the sake of illustrative clarity, the full circuit layout of a current regulator for one of the amplifying arrangements 400, 650 is not illustrated. To operate as an output interface for a Class A amplifier, (nly) one of the transistors M_{CR1}, M_{CR1P} of each amplifying arrangement operates as a first current source transistor of a current regulator. The other transistor may operate as a pass device.

In another example, the transistors M_{CR1}, M_{CR1P} may instead function as pass devices for a push-pull output stage. Other elements of such a push-pull output stage may also be present, e.g., a quiescent current bias regulation circuit or the like). Put another way, each first current source transistor M_{CR1}, M_{CR1P} may be replaced by a respective push-pull output stage. In such a configuration, the single-ended amplifying arrangement may operate as an output interface for a Class AB amplifier.

The second output node N_{OUT2} of the first amplifying arrangement 400 is connected to the second output node N_{OUT2P} of the second amplifying arrangement 650. This provides a single output node N_{OUT2X} that provides a single-ended amplifying output.

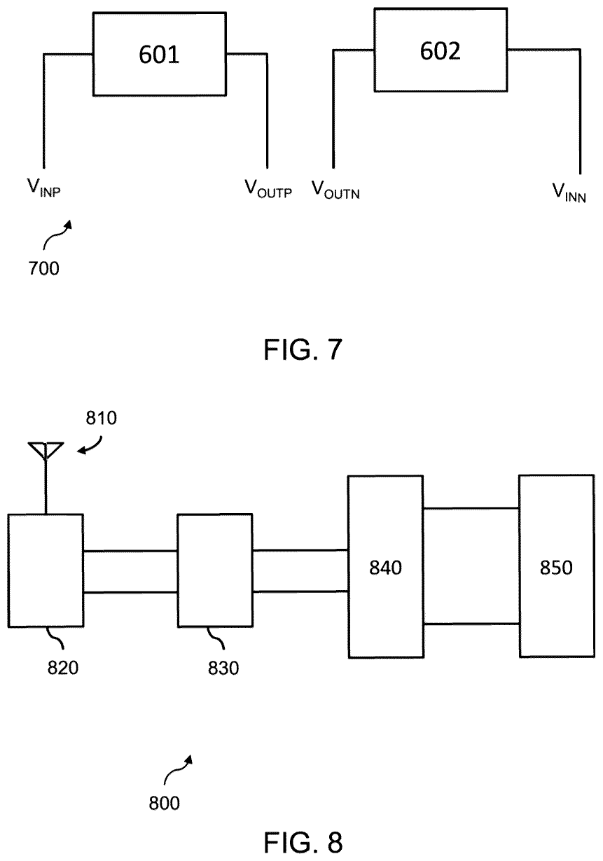

FIG. 7 illustrates a differential output interface 700, also known as an output stage. The differential output interface can be configured for acting as an output interface for a Class A differential amplifier or a Class AB amplifier, as later explained.

The output interface comprises two single-ended amplifying arrangements 601, 602 (e.g., embodied as the single-ended amplifying arrangement previously disclosed). Each single-ended amplifying arrangement 601, 602 is configured to amplify a different output of the Class A differential amplifier. A first single-ended amplifying arrangement 601 amplifies a first signal V_{INP} to produce a first amplified signal V_{OUTP} and a second single-ended amplifying arrangement 602 amplifies a second signal V_{INN} to produce a second amplified signal V_{OUTN}. The difference between the first signal V_{INP} and the second signal V_{INN} defines the differential input to the differential output interface 700 and the difference between the first amplified signal V_{OUTP} and the second amplified signal V_{OUTN} defines the differential output of the differential output interface 700.

To define a Class A differential amplifier, (only) one amplifying arrangement 601, 602 comprises a current regulator. In particular, where each amplifying arrangement is configured as illustrated in FIG. 6, then one of the first current source transistors M_{CR1}, M_{CR1P} is present and each operates as first current source transistor of a current regulator (e.g., as embodied in FIG. 4).

To define a Class AB differential amplifier, the output interface 700 comprises a push-pull output stage. In particular, where each amplifying arrangement is configured as illustrated in FIG. 6, then the transistors M_{CR1}, M_{CR1P} may form part of a push-pull output stage, e.g., together with a quiescent current regulation arrangement. In particular, each transistor may operate as a push-pull pass device.

FIG. 8 illustrates a radar receiving arrangement 800 in which proposed implementations can be integrated or employed. The skilled person will appreciate that this is merely an example of a radar receiving arrangement, and that any herein proposed amplifying arrangement or amplifier arrangement may be incorporated into a wide variety of radar receiving arrangements.

The radar receiving arrangement comprises an antenna arrangement 810 (for receiving radio waves), a matching network 820, a radiofrequency (RF) frontend 830, a baseband processing arrangement 840 and an analogue-to-digital converter 850.

The antenna arrangement 810 comprises one or more antenna for receiving radio waves. Each antenna generates a sensing signal responsive to the radio waves, as is well known in the art.

Any herein proposed amplifier arrangement or amplifying arrangement may be integrated, for instance, into at least the baseband processing arrangement 840.

### Aspects

In addition to the above described aspects, the following aspects are disclosed.

Aspect 1 is a common-gate amplifier arrangement comprising: a common-gate amplifier configured to receive a voltage at an input node and to produce a first voltage based on the received voltage at an intermediate node; and an inner regulated cascode connected to the intermediate node, wherein the inner regulated cascode is configured to amplify the first voltage to produce an amplified voltage at an output node.

Aspect 2 is the common-gate amplifier arrangement of aspect 1 wherein the common-gate amplifier is a regulated common-gate amplifier comprising:
a first transistor having a first source, a first gate and a first drain, wherein:
the first drain is directly connected to the intermediate node; and
the first source is connected to a ground or reference voltage,
a diode-connected transistor having a second source, a second gate and a second drain,
wherein the second source is connected to the input node and the first gate is connected to the second gate.

Aspect 3 is the common-gate amplifier arrangement of aspect 2, wherein the common-gate amplifier comprises a first resistive arrangement connecting the first source to the ground or reference voltage.

Aspect 4 is the common-gate amplifier arrangement of aspect 2 or 3, wherein the common-gate amplifier further comprises a first current source configured to provide a current to the second drain.

Aspect 5 is the common-gate amplifier arrangement of any of aspects 1 to 4, wherein the inner regulated cascode comprises:
a first cascode transistor having a third source, a third gate and a third drain, wherein the third gate is connected to the intermediate node and the third source is connected to a ground or reference voltage; and
a second cascode transistor having a fourth source, a fourth gate and a fourth drain, wherein the fourth drain is connected to the output node, the fourth gate is connected to the third drain and the fourth source is connected to the intermediate node.

Aspect 6 is the common-gate amplifier arrangement of aspect 5, wherein the inner regulated cascode further comprises:
a second current source configured to provide a current to the third drain; and
a third current source configured to provide a current to the fourth drain.

Aspect 7 is the common-gate amplifier arrangement of aspect 6, wherein the current provided by the second current source and the current provided by the third current source are substantially the same.

Aspect 8 is an amplifying arrangement comprising:
the common gate amplifier arrangement of any of aspects 1 to 7;
a current regulator connected between the input node of the common gate amplifier arrangement and a ground or reference voltage; and
a pass transistor having a fifth source, a fifth gate and a fifth drain, wherein the fifth source is connected to the input node of the common gate amplifier arrangement, the fifth gate is connected to the output node of the inner regulated cascode and the fifth drain is connected to a second output node.

Aspect 9 is the amplifying arrangement of aspect 8, wherein the current regulator comprises a current source arrangement connected between the input node of the common gate amplifier and a ground or reference voltage.

Aspect 10 is the amplifying arrangement of aspect 8, wherein the current regulator is a second resistive arrangement connected between the input node of the common gate amplifier and a ground or reference voltage.

Aspect 11 is a single-ended amplifying arrangement comprising:
a first amplifying arrangement comprising the amplifying arrangement of any of aspects 8 to 10, wherein each transistor in the first amplifying arrangement is an NFET; and
a second, different amplifying arrangement comprising the amplifying arrangement of any of aspects 8 to 10, wherein each transistor in the second amplifying arrangement is a PFET, wherein the second output node of the first amplifying arrangement is connected to the second output node of the second amplifying arrangement.

Aspect 12 is a differential-output interface arrangement comprising:
a first single-ended amplifying arrangement comprising the single-ended amplifying arrangement of aspect 11 configured to process a first signal; and
a second, different single-ended amplifying arrangement comprising the single-ended amplifying arrangement of aspect 11 configured to process a second signal, wherein the difference between the first signal and the second signal defines a differential signal.

Aspect 13 is an amplifying arrangement comprising:
the common gate amplifier arrangement of any of aspects 1 to 7;
a push-pull output stage connected between the input node of the common gate amplifier arrangement and a ground or reference voltage; and
a pass transistor having a fifth source, a fifth gate and a fifth drain, wherein the fifth source is connected to the input node of the common gate amplifier arrangement, the fifth gate is connected to the output node of the inner regulated cascode and the fifth drain is connected to a second output node.

Aspect 14 is a single-ended amplifying arrangement comprising:

a third amplifying arrangement comprising the amplifying arrangement of aspect 13, wherein each transistor in the third amplifying arrangement is an NFET; and
a fourth, different amplifying arrangement comprising the amplifying arrangement of aspect 13, wherein each transistor in the fourth amplifying arrangement is a PFET, wherein the second output node of the third amplifying arrangement is connected to the second output node of the fourth amplifying arrangement.

Aspect 15 is a differential-output interface arrangement comprising:
a third single-ended amplifying arrangement comprising the single-ended amplifying arrangement of aspect 14 configured to process a third signal; and
a fourth, different single-ended amplifying arrangement comprising the single-ended amplifying arrangement of aspect 14 configured to process a fourth signal, wherein the difference between the third signal and the fourth signal defines a differential signal.

Aspect 16 is a radar receiving arrangement comprising the common-gate amplifier arrangement of any of aspects 1 to 7.

Aspect 17: A single-ended amplifying arrangement, comprising: a first amplifying arrangement comprising: a first common gate amplifier arrangement, comprising: a first common-gate amplifier configured to receive a first input voltage at a first input node and produce, based on the first input voltage, a first voltage at a first intermediate node; and a first inner regulated cascode connected to the first intermediate node, wherein the first inner regulated cascode is configured to amplify the first voltage to produce a first amplified voltage at a first output node; a first current regulator connected between the first input node of the first common gate amplifier arrangement and a ground voltage or a reference voltage; and a first pass transistor having a first source, a first gate, and a first drain, wherein the first source is connected to the first input node of the first common gate amplifier arrangement, the first gate is connected to the first output node of the first inner regulated cascode, and the first drain is connected to a second output node, wherein each transistor of the first amplifying arrangement is an n-channel field-effect transistor (NFET); and a second amplifying arrangement comprising: a second common gate amplifier arrangement, comprising: a second common-gate amplifier configured to receive a second input voltage at a second input node and produce, based on the second input voltage, a second voltage at a second intermediate node; and a second inner regulated cascode connected to the second intermediate node, wherein the second inner regulated cascode is configured to amplify the second voltage to produce a second amplified voltage at a third output node; a second current regulator connected between the second input node of the second common gate amplifier arrangement and the ground voltage or the reference voltage; and a second pass transistor having a second source, a second gate, and a second drain, wherein the second source is connected to the second input node of the second common gate amplifier arrangement, the second gate is connected to the third output node of the second inner regulated cascode, and the second drain is connected to a fourth output node, wherein each transistor of the second amplifying arrangement is a p-channel field-effect transistor (PFET), and wherein the second output node of the first amplifying arrangement is connected to the fourth output node of the second amplifying arrangement.

Aspect 18: A differential-output interface arrangement, comprising: a first single-ended amplifying arrangement configured to process a first signal; and a second single-ended amplifying arrangement configured to process a second signal, wherein the difference between the first signal and the second signal defines a differential signal.

Aspect 19: An amplifying arrangement, comprising: a common gate amplifier arrangement, comprising: a common-gate amplifier configured to receive a voltage at an input node and produce, based on the voltage, a first voltage at an intermediate node; and an inner regulated cascode connected to the intermediate node, wherein the inner regulated cascode is configured to amplify the first voltage to produce an amplified voltage at an output node; a push-pull pass device connected between the input node of the common gate amplifier arrangement and a ground voltage or a reference voltage; and a further cascode transistor having a fifth source, a fifth gate, and a fifth drain, wherein the fifth source is connected to the input node of the common gate amplifier arrangement, the fifth gate is connected to the output node of the inner regulated cascode, and the fifth drain is connected to a second output node.

Aspect 20: A single-ended amplifying arrangement, comprising: a first amplifying arrangement comprising: a first common gate amplifier arrangement comprising: a first common-gate amplifier configured to receive a first input voltage at a first input node and produce, based on the first input voltage, a first voltage at a first intermediate node; and a first inner regulated cascode connected to the first intermediate node, wherein the first inner regulated cascode is configured to amplify the first voltage to produce a first amplified voltage at a first output node; a first push-pull pass device connected between the first input node of the first common gate amplifier arrangement and a ground voltage or a reference voltage; and a first further cascode transistor having a first source, a first gate, and a first drain, wherein the first source is connected to the first input node of the first common gate amplifier arrangement, the first gate is connected to the first output node of the first inner regulated cascode, and the first drain is connected to a second output node, wherein each transistor in the first amplifying arrangement is an n-channel field-effect transistor (NFET); and a second amplifying arrangement comprising: a second common gate amplifier arrangement comprising: a second common-gate amplifier configured to receive a second input voltage at a second input node and produce, based on the second input voltage, a second voltage at a second intermediate node; and a second inner regulated cascode connected to the second intermediate node, wherein the second inner regulated cascode is configured to amplify the second voltage to produce a second amplified voltage at a third output node; a second push-pull pass device connected between the second input node of the second common gate amplifier arrangement and a ground voltage or a reference voltage; and a second further cascode transistor having a second source, a second gate, and a second drain, wherein the second source is connected to the second input node of the second common gate amplifier arrangement, the second gate is connected to the third output node of the second inner regulated cascode, and the second drain is connected to a fourth output node, wherein each transistor in the second amplifying arrangement is a p-channel field-effect transistor (PFET), wherein the second output node of the first amplifying arrangement is connected to the fourth output node of the second amplifying arrangement.

Aspect 21: A differential-output interface arrangement comprising: a first single-ended amplifying arrangement configured to process a first signal; and a second single-ended amplifying arrangement configured to process a second signal, wherein the difference between the first signal and the second signal defines a differential signal.

Aspect 22: The differential-output interface arrangement of Aspect 18, wherein the first single-ended amplifying arrangement comprises: a first amplifying arrangement comprising: a first common gate amplifier arrangement, comprising: a first common-gate amplifier configured to receive a first input voltage at a first input node and produce, based on the first input voltage, a first voltage at a first intermediate node; and a first inner regulated cascode connected to the first intermediate node, wherein the first inner regulated cascode is configured to amplify the first voltage to produce a first amplified voltage at a first output node; a first current regulator connected between the first input node of the first common gate amplifier arrangement and a ground voltage or a reference voltage; and a first pass transistor having a first source, a first gate, and a first drain, wherein the first source is connected to the first input node of the first common gate amplifier arrangement, the first gate is connected to the first output node of the first inner regulated cascode, and the first drain is connected to a second output node, wherein each transistor of the first amplifying arrangement is an n-channel field-effect transistor (NFET); and a second amplifying arrangement comprising: a second common gate amplifier arrangement, comprising: a second common-gate amplifier configured to receive a second input voltage at a second input node and produce, based on the second input voltage, a second voltage at a second intermediate node; and a second inner regulated cascode connected to the second intermediate node, wherein the second inner regulated cascode is configured to amplify the second voltage to produce a second amplified voltage at a third output node; a second current regulator connected between the second input node of the second common gate amplifier arrangement and the ground voltage or the reference voltage; and a second pass transistor having a second source, a second gate, and a second drain, wherein the second source is connected to the second input node of the second common gate amplifier arrangement, the second gate is connected to the third output node of the second inner regulated cascode, and the second drain is connected to a fourth output node, wherein each transistor of the second amplifying arrangement is a p-channel field-effect transistor (PFET), and wherein the second output node of the first amplifying arrangement is connected to the fourth output node of the second amplifying arrangement.

Aspect 23: The differential-output interface arrangement of Aspect 22, wherein the second single-ended amplifying arrangement comprises: a third amplifying arrangement comprising: a third common gate amplifier arrangement, comprising: a third common-gate amplifier configured to receive a third input voltage at a third input node and produce, based on the third input voltage, a third voltage at a third intermediate node; and a third inner regulated cascode connected to the third intermediate node, wherein the third inner regulated cascode is configured to amplify the third voltage to produce a third amplified voltage at a fifth output node; a third current regulator connected between the third input node of the third common gate amplifier arrangement and the ground voltage or the reference voltage; and a third pass transistor having a third source, a third gate, and a third drain, wherein the third source is connected to the third input node of the third common gate amplifier arrangement, the third gate is connected to the fifth output node of the third inner regulated cascode, and the third drain is connected to a sixth output node, wherein each transistor of the third amplifying arrangement is an NFET; and a fourth amplifying arrangement comprising: a fourth common gate amplifier arrangement, comprising: a fourth common-gate amplifier configured to receive a fourth input voltage at a fourth input node and produce, based on the fourth input voltage, a fourth voltage at a fourth intermediate node; and a fourth inner regulated cascode connected to the fourth intermediate node, wherein the fourth inner regulated cascode is configured to amplify the fourth voltage to produce a fourth amplified voltage at a seventh output node; a fourth current regulator connected between the fourth input node of the fourth common gate amplifier arrangement and the ground voltage or the reference voltage; and a fourth pass transistor having a fourth source, a fourth gate, and a fourth drain, wherein the fourth source is connected to the fourth input node of the fourth common gate amplifier arrangement, the fourth gate is connected to the seventh output node of the fourth inner regulated cascode, and the fourth drain is connected to and eighth output node, wherein each transistor of the fourth amplifying arrangement is a PFET, and wherein the sixth output node of the third amplifying arrangement is connected to the eighth output node of the fourth amplifying arrangement.

Aspect 24: The differential-output interface arrangement of Aspect 21, wherein the first single-ended amplifying arrangement comprises: a first amplifying arrangement comprising: a first common gate amplifier arrangement comprising: a first common-gate amplifier configured to receive a first input voltage at a first input node and produce, based on the first input voltage, a first voltage at a first intermediate node; and a first inner regulated cascode connected to the first intermediate node, wherein the first inner regulated cascode is configured to amplify the first voltage to produce a first amplified voltage at a first output node; a first push-pull pass device connected between the first input node of the first common gate amplifier arrangement and a ground voltage or a reference voltage; and a first further cascode transistor having a first source, a first gate, and a first drain, wherein the first source is connected to the first input node of the first common gate amplifier arrangement, the first gate is connected to the first output node of the first inner regulated cascode, and the first drain is connected to a second output node, wherein each transistor in the first amplifying arrangement is an n-channel field-effect transistor (NFET); and a second amplifying arrangement comprising: a second common gate amplifier arrangement comprising: a second common-gate amplifier configured to receive a second input voltage at a second input node and produce, based on the second input voltage, a second voltage at a second intermediate node; and a second inner regulated cascode connected to the second intermediate node, wherein the second inner regulated cascode is configured to amplify the second voltage to produce a second amplified voltage at a third output node; a second push-pull pass device connected between the second input node of the second common gate amplifier arrangement and a ground voltage or a reference voltage; and a second further cascode transistor having a second source, a second gate, and a second drain, wherein the second source is connected to the second input node of the second common gate amplifier arrangement, the second gate is connected to the third output node of the second inner regulated cascode, and the second drain is connected to a fourth output node, wherein each transistor in the second amplifying arrangement is a p-channel field-effect transistor (PFET), wherein the second output node of the first amplifying arrangement is connected to the fourth output node of the second amplifying arrangement.

Aspect 25: The differential-output interface arrangement of Aspect 24, wherein the second single-ended amplifying arrangement comprises: a third amplifying arrangement comprising: a third common gate amplifier arrangement comprising: a third common-gate amplifier configured to receive a third input voltage at a third input node and produce, based on the third input voltage, a third voltage at a third intermediate node; and a third inner regulated cascode connected to the third intermediate node, wherein the third inner regulated cascode is configured to amplify the third voltage to produce a third amplified voltage at a fifth output node; a third push-pull pass device connected between the third input node of the third common gate amplifier arrangement and a ground voltage or a reference voltage; and a third further cascode transistor having a third source, a third gate, and a third drain, wherein the third source is connected to the third input node of the third common gate amplifier arrangement, the third gate is connected to the fifth output node of the third inner regulated cascode, and the third drain is connected to a sixth output node, wherein each transistor in the third amplifying arrangement is an NFET; and a fourth amplifying arrangement comprising: a fourth common gate amplifier arrangement comprising: a fourth common-gate amplifier configured to receive a fourth input voltage at a fourth input node and produce, based on the fourth input voltage, a fourth voltage at a fourth intermediate node; and a fourth inner regulated cascode connected to the fourth intermediate node, wherein the fourth inner regulated cascode is configured to amplify the fourth voltage to produce a fourth amplified voltage at a seventh output node; a fourth push-pull pass device connected between the fourth input node of the fourth common gate amplifier arrangement and a ground voltage or a reference voltage; and a fourth further cascode transistor having a fourth source, a fourth gate, and a fourth drain, wherein the fourth source is connected to the fourth input node of the fourth common gate amplifier arrangement, the fourth gate is connected to the seventh output node of the fourth inner regulated cascode, and the fourth drain is connected to a eighth output node, wherein each transistor in the fourth amplifying arrangement is a PFET, wherein the sixth output node of the first amplifying arrangement is connected to the eighth output node of the fourth amplifying arrangement.

The radar receiving arrangement may comprise an antenna arrangement, comprising one or more antennae. The common-gate amplifier arrangement may be configured to amplify one or more signals that are responsive to one or more received radio waves by the antenna arrangement.

Although specific aspects have been illustrated and described herein, it will be appreciated by those of ordinary skill in the art that a variety of alternate and/or equivalent implementations may be substituted for the specific aspects shown and described without departing from the scope of the present implementation. This application is intended to cover any adaptations or variations of the specific aspects discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all aspects and implementations outlined in the present document are principally intended expressly to be only for explanatory purposes to help the reader in understanding the principles of the proposed methods and systems. Furthermore, all statements herein providing principles, aspects, and implementations of the implementation, as well as specific aspects thereof, are intended to encompass equivalents thereof.

1. A common-gate amplifier arrangement, comprising:
a common-gate amplifier configured to receive a voltage at an input node and produce, based on the voltage, a first voltage at an intermediate node; and
an inner regulated cascode connected to the intermediate node, wherein the inner regulated cascode is configured to amplify the first voltage to produce an amplified voltage at an output node.

2. The common-gate amplifier arrangement of claim 1, wherein the common-gate amplifier is a regulated common-gate amplifier comprising:
a first transistor having a first source, a first gate, and a first drain,
wherein the first drain is directly connected to the intermediate node, and
wherein the first source is connected to a ground voltage or a reference voltage; and
a diode-connected transistor having a second source, a second gate, and a second drain,
wherein the second source is connected to the input node, and
wherein the first gate is connected to the second gate.

3. The common-gate amplifier arrangement of claim 2, wherein the common-gate amplifier comprises a first resistive arrangement connecting the first source to the ground voltage or the reference voltage.

4. The common-gate amplifier arrangement of claim 2, wherein the common-gate amplifier further comprises a first current source configured to provide a current to the second drain.

5. The common-gate amplifier arrangement of claim 1, wherein the inner regulated cascode comprises:
a first cascode transistor having a third source, a third gate, and a third drain, wherein the third gate is connected to the intermediate node and the third source is connected to a ground voltage or a reference voltage; and
a second cascode transistor having a fourth source, a fourth gate, and a fourth drain, wherein the fourth drain is connected to the output node, the fourth gate is connected to the third drain, and the fourth source is connected to the intermediate node.

6. The common-gate amplifier arrangement of claim 5, wherein the inner regulated cascode further comprises:
a second current source configured to provide a current to the third drain; and
a third current source configured to provide a current to the fourth drain.

7. The common-gate amplifier arrangement of claim 6, wherein the current provided by the second current source and the current provided by the third current source are substantially the same.

8. An amplifying arrangement comprising:
a common gate amplifier arrangement, comprising:
a common-gate amplifier configured to receive a voltage at an input node and produce, based on the voltage, a first voltage at an intermediate node; and
an inner regulated cascode connected to the intermediate node, wherein the inner regulated cascode is configured to amplify the first voltage to produce an amplified voltage at an output node;
a current regulator connected between the input node of the common gate amplifier arrangement and a ground voltage or a reference voltage; and
a pass transistor having a fifth source, a fifth gate, and a fifth drain,
wherein the fifth source is connected to the input node of the common gate amplifier arrangement, the fifth gate is connected to the output node of the inner regulated cascode, and the fifth drain is connected to a second output node.

9. The amplifying arrangement of claim 8, wherein the current regulator comprises a current source arrangement connected between the input node of the common gate amplifier arrangement and the ground voltage or the reference voltage.

10. The amplifying arrangement of claim 8, wherein the current regulator is a second resistive arrangement connected between the input node of the common gate amplifier arrangement and the ground voltage or the reference voltage.

11. A single-ended amplifying arrangement, comprising:
a first amplifying arrangement comprising:
a first common gate amplifier arrangement, comprising:
a first common-gate amplifier configured to receive a first input voltage at a first input node and produce, based on the first input voltage, a first voltage at a first intermediate node; and
a first inner regulated cascode connected to the first intermediate node, wherein the first inner regulated cascode is configured to amplify the first voltage to produce a first amplified voltage at a first output node;
a first current regulator connected between the first input node of the first common gate amplifier arrangement and a ground voltage or a reference voltage; and
a first pass transistor having a first source, a first gate, and a first drain,
wherein the first source is connected to the first input node of the first common gate amplifier arrangement, the first gate is connected to the first output node of the first inner regulated cascode, and the first drain is connected to a second output node,
wherein each transistor of the first amplifying arrangement is an n-channel field-effect transistor (NFET); and
a second amplifying arrangement comprising:
a second common gate amplifier arrangement, comprising:
a second common-gate amplifier configured to receive a second input voltage at a second input node and produce, based on the second input voltage, a second voltage at a second intermediate node; and
a second inner regulated cascode connected to the second intermediate node, wherein the second inner regulated cascode is configured to amplify the second voltage to produce a second amplified voltage at a third output node;
a second current regulator connected between the second input node of the second common gate amplifier arrangement and the ground voltage or the reference voltage; and
a second pass transistor having a second source, a second gate, and a second drain,
wherein the second source is connected to the second input node of the second common gate amplifier arrangement, the second gate is connected to the third output node of the second inner regulated cascode, and the second drain is connected to a fourth output node,
wherein each transistor of the second amplifying arrangement is a p-channel field-effect transistor (PFET), and
wherein the second output node of the first amplifying arrangement is connected to the fourth output node of the second amplifying arrangement.

12. A differential-output interface arrangement, comprising:
a first single-ended amplifying arrangement configured to process a first signal; and
a second single-ended amplifying arrangement configured to process a second signal,
wherein the difference between the first signal and the second signal defines a differential signal.

13. An amplifying arrangement, comprising:
a common gate amplifier arrangement, comprising:
a common-gate amplifier configured to receive a voltage at an input node and produce, based on the voltage, a first voltage at an intermediate node; and
an inner regulated cascode connected to the intermediate node, wherein the inner regulated cascode is configured to amplify the first voltage to produce an amplified voltage at an output node;
a push-pull pass device connected between the input node of the common gate amplifier arrangement and a ground voltage or a reference voltage; and
a further cascode transistor having a fifth source, a fifth gate, and a fifth drain, wherein the fifth source is connected to the input node of the common gate amplifier arrangement, the fifth gate is connected to the output node of the inner regulated cascode, and the fifth drain is connected to a second output node.

14. A single-ended amplifying arrangement, comprising:
a first amplifying arrangement comprising:
a first common gate amplifier arrangement comprising:
a first common-gate amplifier configured to receive a first input voltage at a first input node and produce, based on the first input voltage, a first voltage at a first intermediate node; and
a first inner regulated cascode connected to the first intermediate node, wherein the first inner regulated cascode is configured to amplify the first voltage to produce a first amplified voltage at a first output node;
a first push-pull pass device connected between the first input node of the first common gate amplifier arrangement and a ground voltage or a reference voltage; and
a first further cascode transistor having a first source, a first gate, and a first drain, wherein the first source is connected to the first input node of the first common gate amplifier arrangement, the first gate is connected to the first output node of the first inner regulated cascode, and the first drain is connected to a second output node,
wherein each transistor in the first amplifying arrangement is an n-channel field-effect transistor (NFET); and
a second amplifying arrangement comprising:
a second common gate amplifier arrangement comprising:
a second common-gate amplifier configured to receive a second input voltage at a second input node and produce, based on the second input voltage, a second voltage at a second intermediate node; and
a second inner regulated cascode connected to the second intermediate node, wherein the second inner regulated cascode is configured to amplify the second voltage to produce a second amplified voltage at a third output node;
a second push-pull pass device connected between the second input node of the second common gate amplifier arrangement and a ground voltage or a reference voltage; and
a second further cascode transistor having a second source, a second gate, and a second drain, wherein the second source is connected to the second input node of the second common gate amplifier arrangement, the second gate is connected to the third output node of the second inner regulated cascode, and the second drain is connected to a fourth output node,
wherein each transistor in the second amplifying arrangement is a p-channel field-effect transistor (PFET),
wherein the second output node of the first amplifying arrangement is connected to the fourth output node of the second amplifying arrangement.

15. A differential-output interface arrangement comprising:
a first single-ended amplifying arrangement configured to process a first signal; and
a second single-ended amplifying arrangement configured to process a second signal,
wherein the difference between the first signal and the second signal defines a differential signal.

16. The differential-output interface arrangement of claim 15, wherein the first single-ended amplifying arrangement comprises:
a first amplifying arrangement comprising:
a first common gate amplifier arrangement comprising:
a first common-gate amplifier configured to receive a first input voltage at a first input node and produce, based on the first input voltage, a first voltage at a first intermediate node; and
a first inner regulated cascode connected to the first intermediate node, wherein the first inner regulated cascode is configured to amplify the first voltage to produce a first amplified voltage at a first output node;
a first push-pull pass device connected between the first input node of the first common gate amplifier arrangement and a ground voltage or a reference voltage; and
a first further cascode transistor having a first source, a first gate, and a first drain, wherein the first source is connected to the first input node of the first common gate amplifier arrangement, the first gate is connected to the first output node of the first inner regulated cascode, and the first drain is connected to a second output node,
wherein each transistor in the first amplifying arrangement is an n-channel field-effect transistor (NFET); and
a second amplifying arrangement comprising:
a second common gate amplifier arrangement comprising:
a second common-gate amplifier configured to receive a second input voltage at a second input node and produce, based on the second input voltage, a second voltage at a second intermediate node; and
a second inner regulated cascode connected to the second intermediate node, wherein the second inner regulated cascode is configured to amplify the second voltage to produce a second amplified voltage at a third output node;
a second push-pull pass device connected between the second input node of the second common gate amplifier arrangement and a ground voltage or a reference voltage; and
a second further cascode transistor having a second source, a second gate, and a second drain, wherein the second source is connected to the second input node of the second common gate amplifier arrangement, the second gate is connected to the third output node of the second inner regulated cascode, and the second drain is connected to a fourth output node,
wherein each transistor in the second amplifying arrangement is a p-channel field-effect transistor (PFET),
wherein the second output node of the first amplifying arrangement is connected to the fourth output node of the second amplifying arrangement.

17. The differential-output interface arrangement of claim 16, wherein the second single-ended amplifying arrangement comprises:
a third amplifying arrangement comprising:
a third common gate amplifier arrangement comprising:
a third common-gate amplifier configured to receive a third input voltage at a third input node and produce, based on the third input voltage, a third voltage at a third intermediate node; and
a third inner regulated cascode connected to the third intermediate node, wherein the third inner regulated cascode is configured to amplify the third voltage to produce a third amplified voltage at a fifth output node;
a third push-pull pass device connected between the third input node of the third common gate amplifier arrangement and a ground voltage or a reference voltage; and
a third further cascode transistor having a third source, a third gate, and a third drain, wherein the third source is connected to the third input node of the third common gate amplifier arrangement, the third gate is connected to the fifth output node of the third inner regulated cascode, and the third drain is connected to a sixth output node,
wherein each transistor in the third amplifying arrangement is an NFET; and
a fourth amplifying arrangement comprising:
a fourth common gate amplifier arrangement comprising:
a fourth common-gate amplifier configured to receive a fourth input voltage at a fourth input node and produce, based on the fourth input voltage, a fourth voltage at a fourth intermediate node; and
a fourth inner regulated cascode connected to the fourth intermediate node, wherein the fourth inner regulated cascode is configured to amplify the fourth voltage to produce a fourth amplified voltage at a seventh output node;
a fourth push-pull pass device connected between the fourth input node of the fourth common gate amplifier arrangement and a ground voltage or a reference voltage; and
a fourth further cascode transistor having a fourth source, a fourth gate, and a fourth drain, wherein the fourth source is connected to the fourth input node of the fourth common gate amplifier arrangement, the fourth gate is connected to the seventh output node of the fourth inner regulated cascode, and the fourth drain is connected to a eighth output node,
wherein each transistor in the fourth amplifying arrangement is a PFET,
wherein the sixth output node of the first amplifying arrangement is connected to the eighth output node of the fourth amplifying arrangement.

18. The differential-output interface arrangement of claim 12, wherein the first single-ended amplifying arrangement comprises:
a first amplifying arrangement comprising:
a first common gate amplifier arrangement, comprising:
a first common-gate amplifier configured to receive a first input voltage at a first input node and produce, based on the first input voltage, a first voltage at a first intermediate node; and
a first inner regulated cascode connected to the first intermediate node, wherein the first inner regulated cascode is configured to amplify the first voltage to produce a first amplified voltage at a first output node;
a first current regulator connected between the first input node of the first common gate amplifier arrangement and a ground voltage or a reference voltage; and
a first pass transistor having a first source, a first gate, and a first drain,
wherein the first source is connected to the first input node of the first common gate amplifier arrangement, the first gate is connected to the first output node of the first inner regulated cascode, and the first drain is connected to a second output node,
wherein each transistor of the first amplifying arrangement is an n-channel field-effect transistor (NFET); and
a second amplifying arrangement comprising:
a second common gate amplifier arrangement, comprising:
a second common-gate amplifier configured to receive a second input voltage at a second input node and produce, based on the second input voltage, a second voltage at a second intermediate node; and
a second inner regulated cascode connected to the second intermediate node, wherein the second inner regulated cascode is configured to amplify the second voltage to produce a second amplified voltage at a third output node;
a second current regulator connected between the second input node of the second common gate amplifier arrangement and the ground voltage or the reference voltage; and
a second pass transistor having a second source, a second gate, and a second drain,
wherein the second source is connected to the second input node of the second common gate amplifier arrangement, the second gate is connected to the third output node of the second inner regulated cascode, and the second drain is connected to a fourth output node,
wherein each transistor of the second amplifying arrangement is a p-channel field-effect transistor (PFET), and
wherein the second output node of the first amplifying arrangement is connected to the fourth output node of the second amplifying arrangement.

19. The differential-output interface arrangement of claim 18, wherein the second single-ended amplifying arrangement comprises:
a third amplifying arrangement comprising:
a third common gate amplifier arrangement, comprising:
a third common-gate amplifier configured to receive a third input voltage at a third input node and produce, based on the third input voltage, a third voltage at a third intermediate node; and
a third inner regulated cascode connected to the third intermediate node, wherein the third inner regulated cascode is configured to amplify the third voltage to produce a third amplified voltage at a fifth output node;
a third current regulator connected between the third input node of the third common gate amplifier arrangement and the ground voltage or the reference voltage; and
a third pass transistor having a third source, a third gate, and a third drain,
wherein the third source is connected to the third input node of the third common gate amplifier arrangement, the third gate is connected to the fifth output node of the third inner regulated cascode, and the third drain is connected to a sixth output node,
wherein each transistor of the third amplifying arrangement is an NFET; and
a fourth amplifying arrangement comprising:
a fourth common gate amplifier arrangement, comprising:
a fourth common-gate amplifier configured to receive a fourth input voltage at a fourth input node and produce, based on the fourth input voltage, a fourth voltage at a fourth intermediate node; and
a fourth inner regulated cascode connected to the fourth intermediate node, wherein the fourth inner regulated cascode is configured to amplify the fourth voltage to produce a fourth amplified voltage at a seventh output node;
a fourth current regulator connected between the fourth input node of the fourth common gate amplifier arrangement and the ground voltage or the reference voltage; and
a fourth pass transistor having a fourth source, a fourth gate, and a fourth drain,
wherein the fourth source is connected to the fourth input node of the fourth common gate amplifier arrangement, the fourth gate is connected to the seventh output node of the fourth inner regulated cascode, and the fourth drain is connected to and eighth output node,
wherein each transistor of the fourth amplifying arrangement is a PFET, and
wherein the sixth output node of the third amplifying arrangement is connected to the eighth output node of the fourth amplifying arrangement.
